(19) United States
(12) Patent Application Publication
(10) Pub. No.: US 2015/0087081 A1
(43) Pub. Date: Mar. 26, 2015

(54) METHOD OF REPAIRING ORGANIC LIGHT EMITTING DISPLAY DEVICE

(71) Applicant: SAMSUNG DISPLAY CO., LTD., Yongin-City (KR)

(72) Inventors: Tae Gon KIM, Cheonan-si (KR); Jin-Yup KIM, Cheonan-si (KR)

(21) Appl. No.: 14/307,697

(22) Filed: Jun. 18, 2014

(30) Foreign Application Priority Data
Sep. 23, 2013 (KR) 10-2013-0112774

(51) Int. Cl. H01L 51/00

(52) U.S. Cl. CPC H01L 51/0023
USPC 438/4

(57) ABSTRACT

A repairing method of an organic light emitting display device includes insulating a first switching element and an organic light emitting layer of a defective pixel from each other, short-circuiting a first dummy line and the organic emission layer at a first location, the first dummy line being adjacent to the defective pixel among a plurality of dummy lines extending in a first direction, short-circuiting the first dummy line and a second switching element at a second location, the second switching element being a dummy element prior to the short-circuiting, and insulating an inner side of the first dummy line and an outer side of the first dummy line from each other.

### CROSS-REFERENCE TO RELATED APPLICATION

Korean Patent Application No. 10-2013-0112774, filed on Sep. 23, 2013, in the Korean Intellectual Property Office, and entitled: “Method Of Repairing Organic Light Emitting Display Device,” is incorporated by reference herein in its entirety.

### BACKGROUND

1. Field

The present disclosure relates to a repairing method of an organic light emitting display device.

2. Description of the Related Art

Flat panel displays that are widely known include, e.g., a liquid crystal display (LCD), a plasma display device (PDP), an organic light emitting diode (OLED) display, an electric field effect display (FED), and an electrophoretic display device. Among the flat panel displays, the organic light emitting diode (OLED) display includes two electrodes and an organic emission layer disposed between the two electrodes, and electrons injected from one electrode and holes injected from the other electrode are combined in the organic emission layer to form excitons such that light is emitted by energy generated from the excitons.

In an organic light emitting diode display, when an overcurrent larger than a normal current flows in some pixels due to characteristic deviations of elements included in each pixel, or due to a disconnection or a short-circuit in a pixel circuit, such overcurrent may be converted into bright locations, generating pixel defects. In addition, other pixel defects, e.g., stains, may be generated due to inflow of foreign matters.

### SUMMARY

An exemplary embodiment provides a repairing method of an organic light emitting display device, including insulating a first switching element and an organic light emitting layer of a defective pixel from each other, short-circuiting a first dummy line and the organic emission layer at a first location, the first dummy line being adjacent to the defective pixel among a plurality of dummy lines extending in a first direction, short-circuiting the first dummy line and a second switching element at a second location, the second switching element being a dummy element prior to the short-circuiting, and insulating an inner side of the first dummy line and an outer side of the first dummy line from each other.

Insulating the inner and outer sides of the first dummy line may include cutting off regions of the first dummy line which are respectively adjacent to the first location and the second location at the outer side of the first dummy line.

The repairing method may further include short-circuiting a second dummy line and a data line at a third location, the second dummy line being adjacent to the first dummy line among the plurality of dummy lines, and the data line being connected to the defective pixel, and short-circuiting a third dummy line and the second dummy line at a fourth location, the third dummy line extending in a second direction intersecting the first direction and being connected to the second switch element.

The repairing method may further include insulating an inner side of the third dummy line from an outer side thereof at the fourth location and at a fifth location, the second switching element and the third dummy line being connected to the fifth location, and the inner side of the third dummy extending from the fourth to the fifth location.

Insulating the inner side of the third dummy line from the outer side thereof may include cutting off regions of the third dummy line which are respectively adjacent to the fourth location and the fifth location at the outer side of the third dummy line.

The repairing method may further include insulating an inner side of the second dummy line from an outer side thereof at a third location, the inner side of the second dummy line extending from the third location to the fourth location.

Insulating the inner side of the second dummy line from the outer side thereof may include cutting off a region of the second dummy line which is adjacent to the third location at the outer side of the second dummy line.

Another exemplary embodiment provides a repairing method of an organic light emitting display device, including insulating a first switching element and an organic light emitting layer of a defective pixel from each other, short-circuiting a first dummy line and the organic emission layer at a first location, a first end of the first dummy line being connected to a second switching element serving as a dummy element, and cutting off a region of the first dummy line located at a second end of the first dummy line with respect to the first location, the region of the first dummy line being adjacent to the first location.

The repairing method may further include cutting off a part of a second dummy line, the second dummy line being adjacent to the second switching element and having a first end connected to a driving chip, and the cut off part of the second dummy line being at a second end thereof with respect to a connection location of the second dummy line and the second switching element, and being adjacent to the connection location.

### BRIEF DESCRIPTION OF THE DRAWINGS

Features will become apparent to those of ordinary skill in the art by describing in detail exemplary embodiments with reference to the attached drawings, in which:

FIG. 1 illustrates a flowchart of a repairing method of an organic light emitting display device in accordance with an exemplary embodiment.

FIG. 2 illustrates a layout view of an organic light emitting display device including first to third dummy lines.

FIG. 3 illustrates a layout view of an organic light emitting display device in which some dummy lines are cut off according to the repairing method of the present exemplary embodiment.

FIG. 4 illustrates a partial circuit diagram of the organic light emitting display device of FIG. 2.

FIG. 5 illustrates a partial circuit diagram of the organic light emitting display device repaired according to the repairing method of the present exemplary embodiment.

FIG. 6 illustrates a flowchart of a repairing method of an organic light emitting display device in accordance with another exemplary embodiment.

FIG. 7 illustrates the organic light emitting display device repaired according to the repairing method of the present exemplary embodiment.

FIG. 8 illustrates an organic light emitting display device repaired according to a repairing method in accordance with yet another exemplary embodiment.

### DETAILED DESCRIPTION

Hereinafter, exemplary embodiments will be described in detail with reference to the attached drawings. As those skilled in the art would realize, the described embodiments may be modified in various different ways, all without limiting or departing from the spirit or scope of the present disclosure. Rather, these embodiments are provided so that this disclosure will be thorough and complete, and will fully convey exemplary implementations to those skilled in the art. The drawings and description are to be regarded as illustrative in nature and not restrictive. Like reference numerals designate like elements throughout the specification.

In addition, the size and thickness of each component shown in the drawings are shown for better understanding and ease of description, but the embodiments are not limited thereto. Further, in the drawings, the thickness of layers, films, panels, regions, etc., may be exaggerated for clarity. When a layer, a film, a plate, an element or the like is described as being arranged “on” or “over” another layer, film, plate, or element, this indicates that the layers, films, plates, or elements are arranged on or over each other directly or with a third layer, film, plate, or element intervening therebetween without the limitation to an upper side thereof on the basis of the gravity direction.

Further, throughout this specification, when a part is described as “comprising (or including)” constituent elements, this indicates that the part may further include other constituent elements unless particularly otherwise defined. Furthermore, when the first part is described as being arranged “on” the second part, this indicates that the first part is arranged at an upper side or a lower side of the second part without the limitation to the upper side thereof on the basis of the gravity direction.

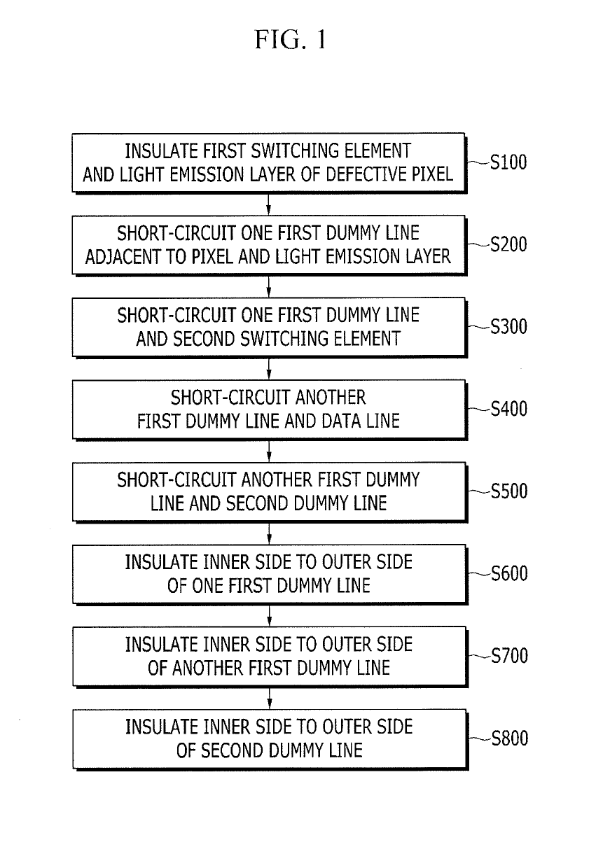

Referring to FIG. 1 to FIG. 5, according to a repairing method of an organic light emitting display device in accordance with an exemplary embodiment, dummy lines, other than dummy lines for connecting pixels to dummy elements, are removed to reduce parasitic capacitance, which may be generated from a dummy line for connecting a defective pixel to a dummy line.

A structure of an organic light emitting display device including first to third dummy lines will now be described before description of a repairing method of an organic light emitting display device in accordance with an exemplary embodiment.

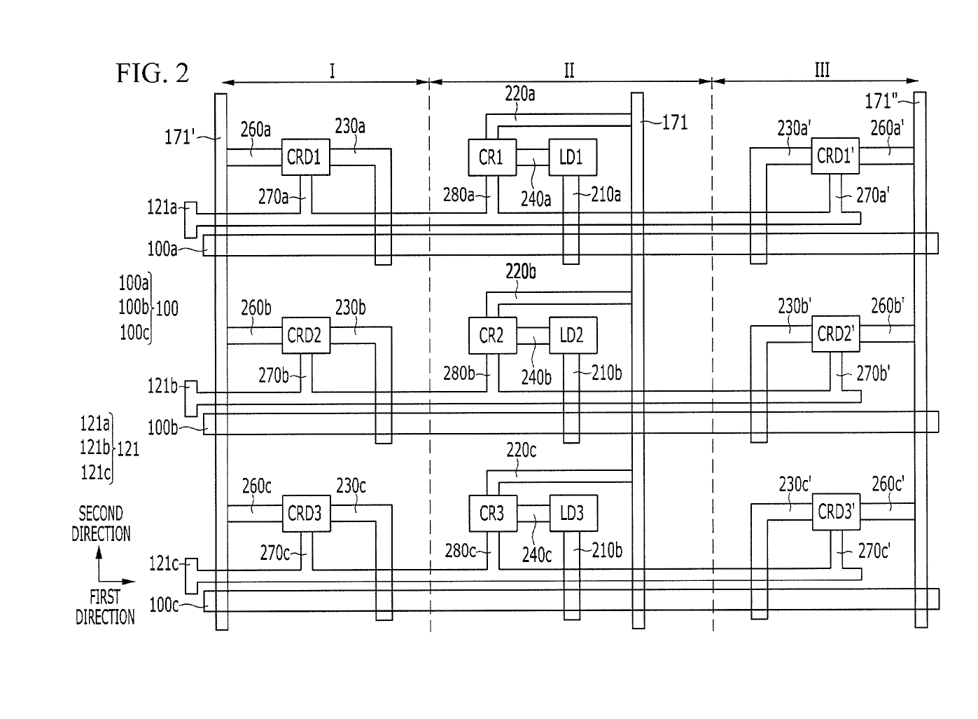

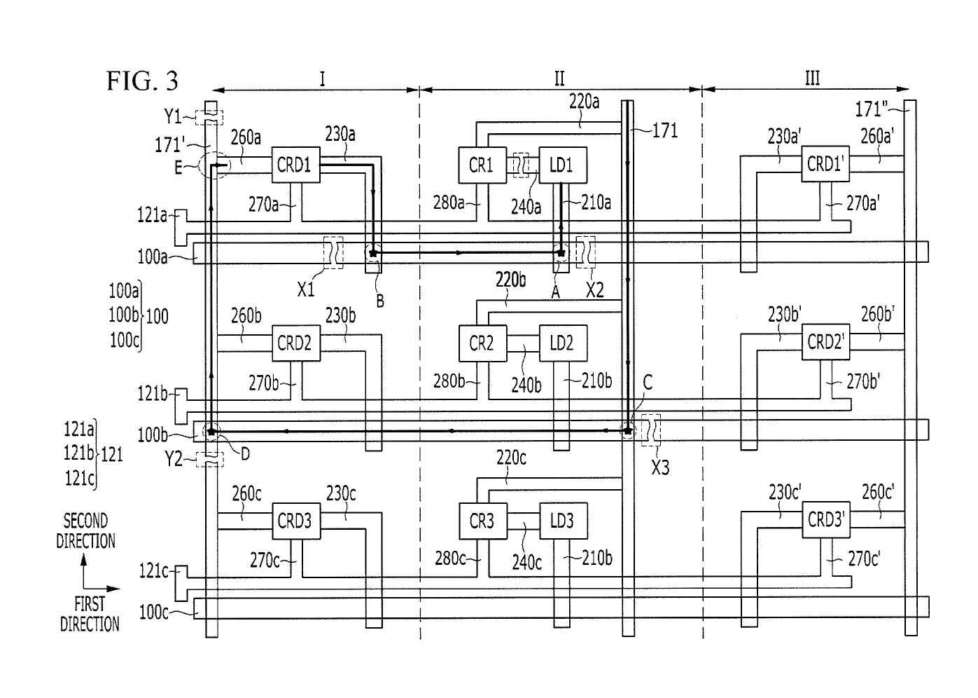

Referring to FIG. 2 and FIG. 3, an organic light emitting display device may include a substrate, a plurality of scan lines 121, a plurality of data lines 171, first switching elements CR1 to CR3, organic emission layers LD1 to LD3, a first dummy line 100, second switching elements CRD1 to CRD3, and second and third dummy lines 171′ and 171″.

The substrate may be formed of an insulating substrate made of, e.g., glass, quartz, ceramic, plastic, or the like, but is not limited thereto. For example, the substrate may be formed of a metal substrate made of stainless steel or the like.

The substrate is divided into a display area II and non-display areas I and III. In the display area II, pixels for displaying images are located, while in the non-display areas I and III, drivers for driving the display area II to display images, and the like are located.

In detail, as shown in FIG. 2 to FIG. 5, the first switching elements CR1 to CR3, the organic emission layers LD1 to LD3, and data lines 171 are located in the display area II. In the non-display areas I and III, the second and third dummy lines 171′ and 171″ are located.

The scan lines 121 may be extended in a first direction over the display and non-display areas I, II, and III to connect to the first and second switching elements CR1 to CR3 and CRD1 to CRD3. For example, a scan line 121a of the scan lines 121 is connected to gate electrodes 270a, 280a, and 270a′ of first through third switching elements CRD1, CR1, and CRD1′, respectively. Further, a connection part formed at one end of a scan line 121 may be connected to a gate driver.

The scan lines 121 may be formed of the same layer as the gate electrodes 270a, 270a′, and 280a. Further, the scan lines 121 may be formed of the same material as the gate electrodes 270a, 270a′, and 280a.

The data lines 171 may be extended in a second direction intersecting the first direction in the display area II. The data lines 171 may be extended to intersect the scan lines 121, respectively. In this case, the data lines 171 are connected to the first switching elements LD1 to LD3. In detail, the data lines 171 are connected to first source electrodes 220a to 220c of the first switching elements CR1 to CR3 to transfer data signals. Further, a connection part formed at one end of a data line 171 may be connected to a data driver.

The data lines 171 may be formed of the same layer as the first source electrodes 220a to 220c. Further, the data lines 171 may be formed of the same material as the first source electrodes 220a to 220c.

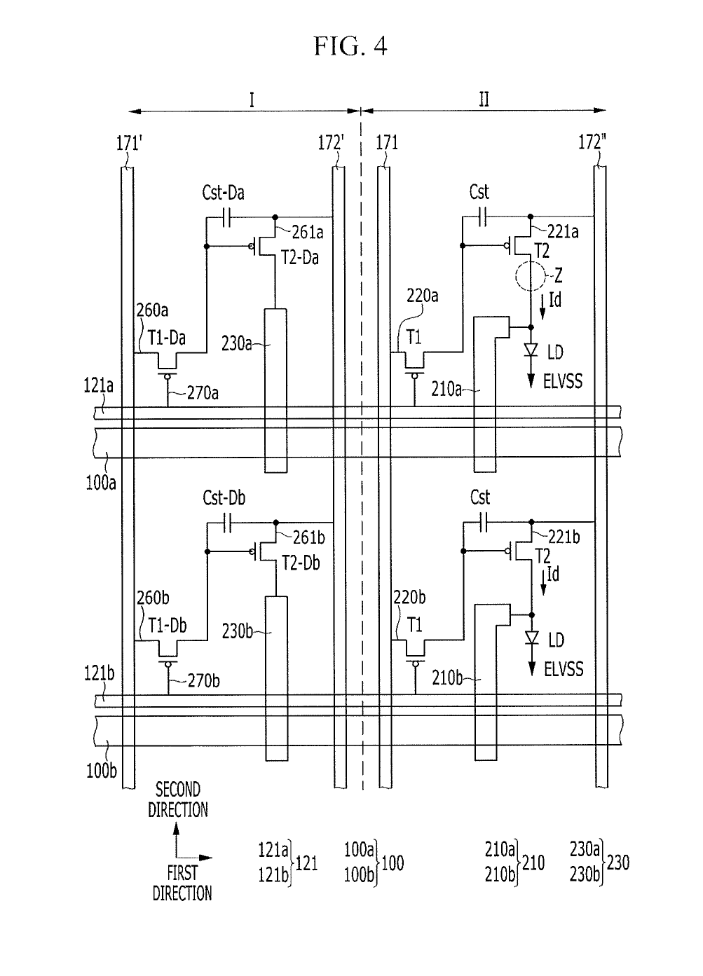

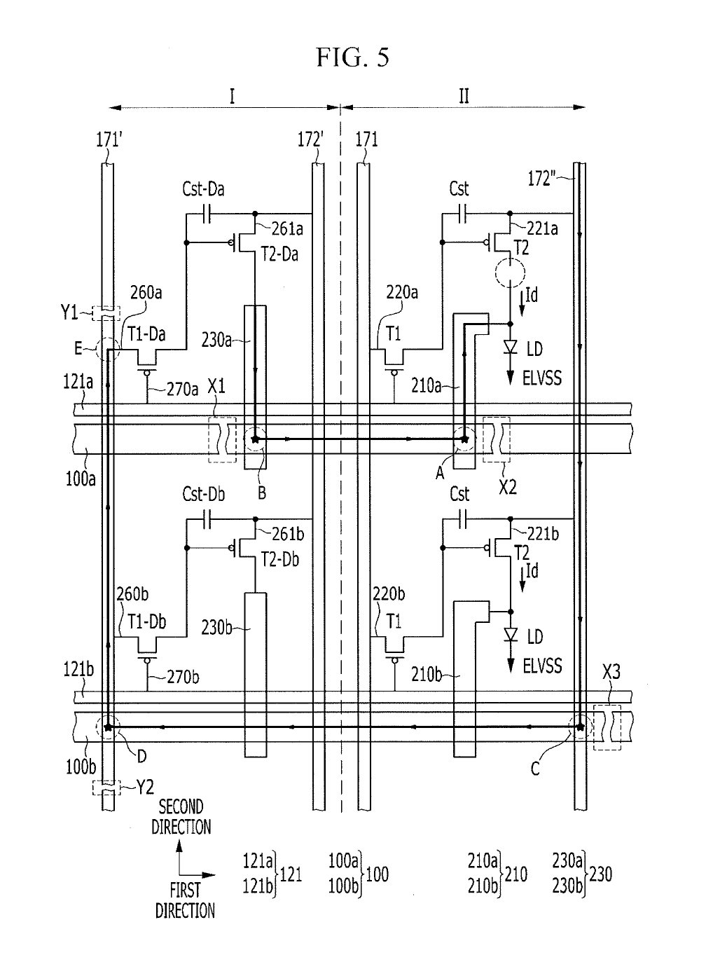

Referring to FIG. 4 and FIG. 5, driving voltage lines 172′ and 172″ are extended in the second direction. The driving voltage line 172′ is located in the non-display area I, while the driving voltage line 172″ is located in the display area II. The driving voltage line 172′ is connected to fourth source electrodes 261a and 261b of the second switching elements CRD1 and CRD2. The driving voltage line 172″ is connected to second source electrodes 221a and 221b of the first switching elements CR1 and CR2.

Each of the first switching elements CR1 to CR3 includes a switching thin film transistor and a driving thin film transistor. Herein, each of the first switching elements CR1 to CR3 may further include a storage capacitor Cst, e.g., the storage capacitor Cst may be any suitable capacitor and a detailed description thereof will be omitted.

The first switching elements CR1 to CR3 respectively drive organic emission layers LD1 to LD3 to be described later. Switching thin film transistors of the first switching elements CR1 to CR3 respectively include first source electrodes 220a, 220b, and 220c, first gate electrodes 280a, 280b, and 280c, and first drain electrodes. As described above, first source electrodes 220a to 220c are connected to the data line 171. The first gate electrodes 280a to 280c of the switching thin film transistors are connected to the scan line 121.

Each driving thin film transistor of the first switching elements CR1 to CR3 includes a second source electrode, a second gate electrode, and a second drain electrode. The driving thin film transistors of the first switching elements CR1 to CR3 may be connected to the organic emission layers LD1 to LD3. As shown in FIG. 2 to FIG. 5, members indicated by reference numerals 240a, 240b, and 240c, which connect the organic emission layers LD1 to LD3 to the first switching elements CR1 to CR3, may respectively be second drain electrodes of the anode or driving thin film transistors. The reference numerals 240a to 240c respectively indicate cut-off areas between the first switching elements CR1 to CR3 and the organic emission layers LD1 to LD3 in the repairing method of an organic light emitting display device in accordance with the present exemplary embodiment. This will be described in detail later.

As shown in FIG. 2 to FIG. 5, members indicated by reference numerals 210a, 210b, and 210c, which overlap with the first dummy lines 100, may respectively be anode electrodes or second drain electrodes. In other words, the first dummy lines 100 may overlap with the anode electrodes or the second drain electrodes in the repairing method of an organic light emitting display device in accordance with the present exemplary embodiment. This will also be described in detail later.

The organic emission layers LD1 to LD3 connected to the first switching elements CR1 to CR3 are formed of a low molecular organic material or a high molecular organic material. Each of the organic emission layers LD1 to LD3 may be formed of a multilayer that includes the emission layer and at least one of a hole injection layer (HIL), a hole transport layer (HTL), an electron transport layer (ETL), and an electron injection layer (EIL). When all of the above layers are included, the HIL is disposed on the anode electrode, and the HTL, the emission layer, the ETL, and the EIL are sequentially layered thereon. The organic emission layers LD 1 to LD3 are identified as colors, e.g., red, green, blue, and the like, according to material types thereof.

The first dummy lines 100 may be extended in the first direction. The first dummy lines 100 may be formed to extend over the display areas II and the non-display areas I and II on the substrate. The first dummy lines 100 may be used to connect defective pixels to dummy elements, i.e., to the second or third switching elements CRD1 to CRD3 or CRD1′ to CRD3′.

Each of the first dummy lines 100 may be disposed between corresponding adjacent scan lines 121. For example, a first dummy line 100a is located between the scan line 121a and an adjacent scan line 121b. Similarly, a first dummy line 100b is located between the scan line 121b and an adjacent scan line 121c.

The first dummy lines 100 are overlapped with the data lines 171. Further, as described above, the first dummy lines 100 may be overlapped with the members indicated by the reference numerals 210a to 210c. In the present exemplary embodiment, the reference numerals 210a to 210c may indicate the anode electrodes or the second drain electrodes.

The first dummy lines 100 are also overlapped with fourth drain electrodes 230a to 230c of the second switching elements CRD1 to CRD3 to be described later. In addition, the first dummy lines 100 are overlapped with the second dummy lines 171′ to be described later in the non-display area I.

In the meantime, the first dummy lines 100 may be formed of the same layer as that of gate electrodes of the first and second switching elements CR1 to CR3 and CRD1 to CRD3. In this case, the first dummy lines 100 may be made of the same material as that of the gate electrodes.

Referring to FIG. 2 to FIG. 5, the second switching elements CRD1 to CRD3 are located in the non-display area I. The second switching elements CRD1 to CRD3 may serve as dummy elements to be connected to the organic emission layer LD1 to LD3 instead of the first switching element CR1 to CR3 of a defective pixel. In this case, each of the second switching elements CRD 1 to CRD3 includes a switching thin film transistor and a driving thin film transistor. Each of the second switching elements CRD1 to CRD3 may further include a storage capacitor Cst-Da or Cst-Db.

The switching thin film transistors of the second switching elements CDR1 to CRD3 respectively include third source electrodes 260a, 260b, and 260c, third gate electrodes 270a, 270b, and 270c, and third drain electrodes. The third source electrodes 260a to 260c are connected to the second dummy lines 171′ to be described later. The third gate electrodes 270a to 270c are connected to the scan lines 121.

The driving thin film transistors of the second switching elements CDR1 to CRD3 respectively include the fourth source electrodes 261a and 261b, fourth gate electrodes, and fourth drain electrodes 230a, 230b, and 230c. As described above, the fourth drain electrodes 230a to 230c are overlapped with the first dummy lines 100. As shown in FIG. 4 and FIG. 5, the fourth source electrodes 261a and 261b are connected to the driving voltage line 172′.

Referring to FIG. 2 and FIG. 3, the third dummy lines 171″ and the third switching elements CRD1′ to CRD3′ may be located in the non-display areas III. The third dummy line 171″ and the third switching elements CRD1′ to CRD3′ respectively correspond to the second dummy line 171′ and the second switching elements CRD 1 to CRD3 located in the non-display area I. The third dummy lines 171″ and the third switching elements CRD1′ to CRD3′ respectively perform the same functions as those of the second dummy lines 171′ and the second switching elements CRD 1 to CRD3, and thus repetitive detailed descriptions are omitted.

The repairing method of an organic light emitting display device in accordance with the exemplary embodiment will now be described with reference to FIG. 1, FIG. 3, and FIG. 5. In the present exemplary embodiment, it is assumed that a defect is generated in a pixel including the first switching element CR1 and the organic emission layer LD1 of the display area I.

First, in a defective pixel, the first switching element CR1 is insulated from the organic emission layer LD1 (S100).

As shown in FIG. 3, member 240a, which connects the first switching element CR1 to the organic emission layer LD1, is cut off. As described above, in the present exemplary embodiment, the member 240a may be the anode electrode or the second drain electrode. As the anode electrode or the second drain electrode is cut off, a current supplied to the organic emission layer LD 1 can be blocked.

In the repairing method of an organic light emitting display device in accordance with the present exemplary embodiment, a laser device may be used to cut off a specific electrode or to connect a plurality of electrodes or layers. However, embodiments are not limited to cutting-off by a laser and any other suitable method of cutting-off or connecting in a typical manufacturing or repairing process of a display device may be applied thereto without being limited to the laser device.

Next, the organic emission layer LD1 and the first dummy line 100a adjacent to a defective layer among the plurality of first dummy lines 100 are short-circuited (S200).

Referring to FIG. 3, the first dummy line 100a is connected to the member 210a to short-circuit the first dummy line 100a and the organic emission layer LD 1. In other words, the first dummy line 100a and the member 210a are connected to each other at a first location A at which they are overlapped with other. As described above, the member 210a may be the anode electrode or the second drain electrode, so the first dummy line 100a can be connected to the anode electrode or the second drain electrode.

Next, the first dummy line 100a and the second switching element CRD1 serving as the dummy element are short-circuited (S300). Herein, the second switching element CRD1 is a second switching element disposed in the first direction in parallel with the first switching element CR1 of the defective pixel.

The first dummy line 100a and the fourth drain electrode 230a are connected to each other when the first dummy line 100a and the second switching element CRD1 are short-circuited, i.e., in operation S300. As described above, the fourth drain electrode 230a of the second switching element CRD1 and the first dummy line 100a are overlapped with each other and connected to each other at a second location B. In other words, at the second location B, the first dummy line 100a and the fourth drain electrode 230a are connected to each other.

Next, the first dummy line 100b adjacent to the first dummy line 100a and the data line 171 are short-circuited (S400). The data line 171 intersects the first dummy line 100b at a third location C at which they are overlapped with each other. In other words, at the third location C, the data line 171 is connected to the first dummy line 100a.

Next, the first dummy line 100b and the second dummy line 171′ are short-circuited (S500). The second dummy line 171′ is adjacent to the second switching element CRD1, and extends in the second direction in the non-display area I. In this case, the first dummy line 100b and the second dummy line 171′ intersect each other at a fourth location D in the non-display area I. Accordingly, the first dummy line 100b and the second dummy line 171′ are connected to each other at the fourth location D.

Next, an inner side of the first dummy line 100a which connects the first location A to the second location B is insulated from an outer side thereof (S600). Herein, in FIG. 3, a region in which the first location A of the first dummy line 100a is connected to the second location B is defined as the inner side of the first dummy line 100a, and the remaining region of the first dummy line 100a, i.e., a region other than the inner side thereof, is defined as the outer side of the first dummy line 100a. That is, the outer side of the first dummy line 100a includes a left side and a right side of the first dummy line 100a with respect to the inner side of the first dummy line 100a.

In detail, in operation S600, the inner side of the first dummy line 100a is separated, i.e., cut off, from the outer side of the first dummy line 100a at regions X1 and X2 illustrated in FIGS. 3 and 5. The region X1 of the first dummy line 100a, which is a region adjacent to the second location B in the first dummy line 100a, is located at the outer side of the first dummy line 100a. The region X2 of the first dummy line 100a, which is adjacent to the first location A, is located at the outer side of the first dummy line 100a. Accordingly, only the inner side of the first dummy line 100a, i.e., a portion of the first dummy line 100a between points A and B, is electrically connected between the organic emission layer LD1 and the second switching element CRD1.

As such, it is possible to remove an unnecessary portion of the first dummy line 100a, i.e., an outer portion of the first dummy line 100a, after the organic light emitting display device is repaired by separating the inner side and the outer side of the first dummy line 100a from each other. As the unnecessary portion of the first dummy line 100a is removed, parasitic capacitance can be reduced.

Next, an inner side of the first dummy line 100b which connects the third location C to the fourth location D is insulated from an outer side thereof (S700). Similar to the first dummy line 100a, in FIG. 3, a region of the first dummy line 100b connecting the third location C to the fourth location D is defined as the inner side of the first dummy line 100b, and the remaining region of the first dummy line 100b, i.e., a region of the first dummy line 100b other than the inner side thereof, is defined as the outer side of the first dummy line 100b. That is, the outer side of the first dummy line 100b includes a right side of the first dummy line 100b with respect to the inner side of the first dummy line 100b.

A region X3 of the first dummy line 100b is cut off in operation S700, so the inner side and the outer side of the first dummy line 100b are insulated, e.g., separated, from each other. The region X3 of the first dummy line 100b, which is a region adjacent to the third location C in the first dummy line 100b, is located at the outer side of the first dummy line 100b. As such, only the inner side of the first dummy line 100b connected between the data line 171 and the second dummy line 171′, so it is possible to remove the unnecessary portion of the first dummy line 100b, i.e., the outer side of the first dummy line 100b, after the organic light emitting display device is repaired by separating the inner side and the outer side of the first dummy line 100b from each other.

Next, an inner side of the second dummy line 171′, which connects the fourth location D to a fifth location E, is insulated from an outer side thereof (S800). Similar to the first dummy line 100a, in FIG. 3, a region in which the fourth location D of the second dummy line 171′ is connected to the fifth location E is defined as the inner side of the second dummy line 171′, and the remaining region of the second dummy line 171′ except the inner side thereof is defined as the outer side of the second dummy line 171′. That is, the outer side of the second dummy line 171′ includes an upper side and a lower side of the second dummy line 171′ with respect to the inner side of the second dummy line 171′.

Regions Y1 and Y2 of the second dummy line 171′ are cut off in operation S800, in which the inner side and the outer side of the second dummy line 171′ are insulated from each other. The region Y1 of the second dummy line 171′, which is a region adjacent to the fifth location E in the second dummy line 171′, is located at the outer side of the second dummy line 171′. The region Y2 of the second dummy line 171′, which is a region adjacent to the fourth location Din the second dummy line 171′, is located at the outer side of the second dummy line 171′.

As described above, it is possible to repair the defective pixel by insulating or short-circuiting the first dummy lines 100a and 100b and the second dummy line 171′. In brief, a defective first switching element CR1 is separated from the organic emission layer LD1, and the second switching element CRD1 is connected to the organic emission layer LD1 via a portion of the first dummy lines 100a. As a result, current flows from the second switching element CRD 1 to the organic emission layer LD 1. Further, a data signal transmitted to the defective first switching element CR1 is also transferred to the second switching element CRD1 through the data line 171, the first dummy line 100b, and the second dummy line 171.′

In the repairing method of an organic light emitting display device in accordance with the present exemplary embodiment, the order of the short-circuiting steps S200 to S500 may be varied. Further, the order of the insulating steps S600 to S800 may be varied.

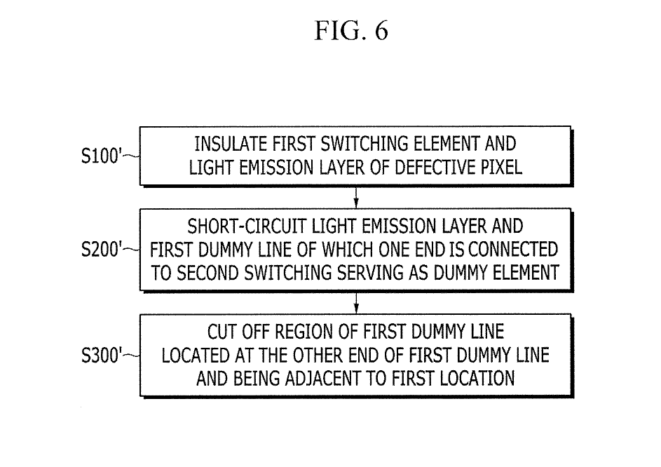

A repairing method of an organic light emitting display device in accordance with another exemplary embodiment will be described with reference to FIG. 6. When the organic light emitting display device of the present exemplary embodiment is described, descriptions for same or similar elements and operations as in the aforementioned exemplary embodiment will be omitted.

Unlike the repairing method of the organic light emitting display device described with reference to FIG. 1 to FIG. 5, in the repairing method of an organic light emitting display device in accordance with the present exemplary embodiment, one end of the first dummy line 100 is connected to the second switching element CRD.

Similar to the repairing method of the organic light emitting display device in accordance with the aforementioned exemplary embodiment, in a defective pixel, a first switching element CR is first insulated from an organic emission layer LD (S100′).

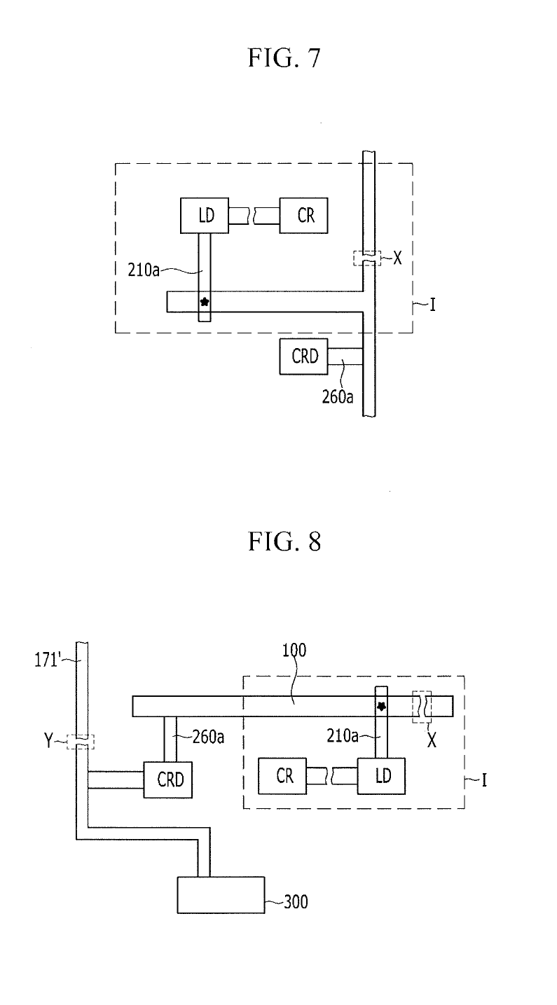

Next, the first dummy line 100 and the organic emission layer LD are short-circuited at a first location (S200′). As shown in FIG. 7, the first dummy line 100 and an anode electrode or the second drain electrode 210a are connected to each other. Herein, the first location is indicated by an asterisk in FIG. 7.

Next, an inner side and an outer side of the first dummy line 100 are insulated from each other (S300′). The inner side of the first dummy line 100 includes a region in which one end of the first dummy line 100 connected to the second switching element CRD is connected to the member indicated by the reference numeral 210a. The outer side of the first dummy line 100 includes the remaining region of the first dummy line 100 except the inner side thereof. The first dummy line 100 is cut off at a boundary region X between the inner side and the outer side.

Referring to FIG. 8, in a repairing method of an organic light emitting display device in accordance with yet another exemplary embodiment, the second dummy line 171′ connected to the second switching element CRD is included, unlike in FIG. 7. A first end of the second dummy line 171′ is connected to a driving chip 300. For example, the driving chip 300 may be a timing controller.

For the second dummy line 171′, the remaining region of the second dummy line 171′, except a region thereof connected to the second switching element CRD, is cut off. In other words, a region Y of the second dummy line 171′ located at the side of a second end of the second dummy line 171′ with respect to a second location of the second dummy line 171′ at which the second dummy line 171′ is connected to the second switching element CRD.

According to the repairing method of an organic light emitting display device in accordance with the exemplary embodiments, it is possible to reduce parasitic capacitance of the organic light emitting display device by removing a remaining dummy line that is not used for transmitting a current or data among the first to third dummy lines used for a defective pixel.

In contrast, a conventional repairing method of defective pixels may use dummy lines that extend along the entire organic light emitting display device. However, the remaining portions of the dummy lines which are not used for transmitting current or data to the defective pixel may cause parasitic capacitances.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A repairing method of an organic light emitting display device, the repairing method comprising:
insulating a first switching element and an organic light emitting layer of a defective pixel from each other;
short-circuiting a first dummy line and the organic emission layer at a first location, the first dummy line being adjacent to the defective pixel among a plurality of dummy lines extending in a first direction;
short-circuiting the first dummy line and a second switching element at a second location, the second switching element being a dummy element prior to the short-circuiting; and
insulating an inner side of the first dummy line and an outer side of the first dummy line from each other.

2. The repairing method as claimed in claim 1, wherein insulating the inner and outer sides of the first dummy line includes cutting off regions of the first dummy line which are respectively adjacent to the first location and the second location at the outer side of the first dummy line.

3. The repairing method as claimed in claim 1, further comprising:
short-circuiting a second dummy line and a data line at a third location, the second dummy line being adjacent to the first dummy line among the plurality of dummy lines, and the data line being connected to the defective pixel; and
short-circuiting a third dummy line and the second dummy line at a fourth location, the third dummy line extending in a second direction intersecting the first direction and being connected to the second switch element.

4. The repairing method as claimed in claim 3, further comprising insulating an inner side of the third dummy line from an outer side thereof at the fourth location and at a fifth location, the second switching element and the third dummy line being connected to the fifth location, and the inner side of the third dummy extending from the fourth to the fifth location.

5. The repairing method as claimed in claim 4, wherein insulating the inner side of the third dummy line from the outer side thereof includes cutting off regions of the third dummy line which are respectively adjacent to the fourth location and the fifth location at the outer side of the third dummy line.

6. The repairing method as claimed in claim 3, further comprising insulating an inner side of the second dummy line from an outer side thereof at a third location, the inner side of the second dummy line extending from the third location to the fourth location.

7. The repairing method as claimed in claim 6, wherein insulating the inner side of the second dummy line from the outer side thereof includes cutting off a region of the second dummy line which is adjacent to the third location at the outer side of the second dummy line.

8. A repairing method of an organic light emitting display device, the repairing method comprising:
insulating a first switching element and an organic light emitting layer of a defective pixel from each other;
short-circuiting a first dummy line and the organic emission layer at a first location, a first end of the first dummy line being connected to a second switching element serving as a dummy element; and
cutting off a region of the first dummy line located at a second end of the first dummy line with respect to the first location, the region of the first dummy line being adjacent to the first location.

9. The repairing method as claimed in claim 8, further comprising cutting off a part of a second dummy line, the second dummy line being adjacent to the second switching element and having a first end connected to a driving chip, and the cut off part of the second dummy line being at a second end thereof with respect to a connection location of the second dummy line and the second switching element, and being adjacent to the connection location.
